(19) United States
(12) Patent Application Publication
(10) Pub. No.: US 2006/0237695 A1
(43) Pub. Date: Oct. 26, 2006

(54) Copolymers of soluble poly(thiophenes) with improved electronic performance

(75) Inventors: Shawn P. Williams, Pittsburgh, PA (US); Darin W. Laird, Pittsburgh, PA (US); Caton C. Goodman, Pittsburgh, PA (US); Traian Sarbu, Pittsburgh, PA (US); Shijun Jia, Pittsburgh, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 11/376,550

(22) Filed: Mar. 16, 2006

Related U.S. Application Data
(60) Provisional application No. 60/661,934, filed on Mar. 16, 2005.

(51) Int. Cl. H01B 1/12

(52) U.S. Cl. 252/500

(57) ABSTRACT

Polythiophene copolymers having tunable work functions and oxidation voltage onset. The ratio of monomer can be varied to achieve the desired property for a particular application. One monomer can be unsubstituted thiophene. The copolymer microstructure can be random. Another monomer can be a 3-substituted thiophene such as 3-alkyl or a heteroatom substituted substituent. Heterojunction polymer photovoltaic cells can be fabricated with excellent voltage onset properties compared to devices having corresponding homopolymers.

### RELATED APPLICATIONS

This applications claims the benefit of provisional patent application Ser. No. 60/661,934 filed Mar. 16, 2005 to Williams et al., which is hereby incorporated by reference in its entirety.

### BACKGROUND

This invention relates generally to the control of the electronic and optical properties of inherently conductive polymers as a method to improve the performance of polymer-based electronic devices such as light emitting diodes, photovoltaic cells, and field effect transistors. These devices and materials are of interest in, for example, displays, off-grid power generation, and low weight, flexible, and printable circuitry. It is of a great importance to improve the performance of currently existing devices including enhancing their efficiencies and tunability. Polythiophenes are particularly useful. See, for example, McCullough et al, J. Chem. Soc., Chem. Commun., 1995, No. 2, pages 135-136. A need exists to provide polymers and copolymers with more closely tailored polymer architectures to satisfy sophisticated application demands. Improved polymerization methods need to be intimately connected to practical device applications. Better performance is needed is parameters such as, for example, work function, oxidation onset, and open circuit voltage. In particular, better photovoltaic materials are needed.

### SUMMARY

The invention is described with use of a non-limiting summary.

One embodiment comprises a composition comprising a soluble, inherently conductive random copolymer comprising at least one 3-alkyl thiophene repeat unit and sufficient amount of unsubstituted thiophene repeat unit to provide the copolymer with a work function of −4.98 eV or lower (i.e., a larger negative value) and with a Vox onset of 0.58 V or higher (i.e., a larger positive value). Alternatively, the work function can be, for example, −5.09 eV or lower. The work function also can be, for example, −5.23 eV or lower. The Vox onset can be at least 0.69 V, or alternatively, at least 0.83 V. Alternatively, the Vox onset can be at least 0.69 V and the work function can be at least −5.09 eV or lower; or the Vox onset can be at least 0.83 V and the work function can be at least −5.23 eV or lower. In one embodiment, the alkyl group can have 11 or fewer carbons. The composition can comprise at least two 3-alkyl thiophene repeat units, or alternatively, at least three 3-alkyl thiophene repeat units. The amount of unsubstituted thiophene repeat unit can be at least about 25 mole % with respect to monomer repeat units, or alternatively, at least about 50 mole % with respect to monomer repeat units, or alternatively, at least about 70 mole % with respect to monomer repeat units.

Another embodiment is a composition comprising a soluble, inherently conductive random copolymer comprising at least one 3-substituted thiophene repeat unit and sufficient amount of unsubstituted thiophene repeat unit to provide the copolymer with a work function of −4.85 eV or lower and with a Vox onset of 0.49 V or higher. The 3-substituent can comprise electron-withdrawing groups or electron-releasing groups, and a given copolymer can have combinations of these different types of groups. The 3-substituted thiophene repeat unit can be, for example, a 3-alkyl substituted thiophene repeat unit, or alternatively, the 3-substituted thiophene repeat unit can be a 3-substituent comprising a heteroatom. The 3-substituted thiophene repeat unit can be a 3-substituent comprising an oxygen heteroatom; the 3-substituted thiophene repeat unit can be a 3-substituent comprising an oxygen heteroatom directly bonded to the thiophene ring. The 3-substituted thiophene repeat unit can be an alkoxy substituent, or alternatively, the 3-substituted thiophene repeat unit can be a polyether substituent. The copolymer can have a work function of −5.133 eV or lower and have a Vox onset of 0.773 V or higher.

Still another embodiment is a composition comprising a soluble, inherently conductive random copolymer comprising at least one 3-substituted thiophene repeat unit, wherein the 3-substituent comprises a heteroatom, and sufficient amount of unsubstituted thiophene repeat unit to provide the copolymer with a work function of −4.85 eV or lower and with a Vox onset of 0.49 V or higher. The work function can be at least −5.133 eV or lower, and the Vox onset can be 0.773 or higher. The heteroatom can be oxygen. The 3-substituent can comprise at least two heteroatoms, or alternatively, at least three heteroatoms. The 3-substituent can comprise an alkoxy group, or the 3-substituent can comprise a polyether group.

Other embodiments include a device comprising the compositions described above and in the claims, wherein the device can be, for example, a solar cell, a light emitting diode, a thin film semiconductor, a thin film conductor, a non-emitting diode, a transistor, an RFID tag, or a capacitor. In particular, multi-layer photovoltaic devices can be prepared.

The following represent additional embodiments:
1) A soluble, inherently conductive copolymer comprising at least one monomer which contains functionality that imparts solubility and at least one monomer which contains functionality that favorably modifies the energy levels of the copolymer to suit an end-use application such as, for example, a photovoltaic application or a light emitting application.
2) Embodiment #1 wherein the copolymer is a random copolymer
3) Embodiment #1 wherein the copolymer is an alternating copolymer
4) Embodiment #1 wherein the copolymer is a block copolymer
5) Embodiment #1 wherein the copolymer is a graft copolymer
6) Embodiments #1 and #4 wherein the copolymer is formed by the linkage of two homopolymers
7) Embodiment #6 wherein the linkage contains a carbonyl functionality or other functionality which includes an sp² hydridization.
8) Embodiments #1-6 wherein the copolymer is regioregular
9) Embodiments #1-6 wherein the copolymer is regiorandom
10) Embodiments #1-8 wherein the copolymer is comprised of two monomers
11) Embodiments #1-8 wherein the copolymer is comprised of three monomers
12) Embodiments #1-8 wherein the copolymer is comprised of more than three monomers
13) Embodiments #1-1 wherein the copolymer contains a thiophene derivative
14) Embodiment #12 wherein the thiophene derivative contains a 3-substituent
15) Embodiment #12 wherein the thiophene derivative contains a 4-substituent
16) Embodiment #12 wherein the thiophene derivative contains both 3- and 4-substituent
17) Embodiment #15 wherein the 3- and 4-substituents are linked to one another
18) Embodiments #1-16 wherein the monomer that modifies the energy level of the copolymer contains a heteroatom functionality
19) Embodiment #17 wherein the heteroatom functionality contains non-bonding electrons
20) Embodiment #17 wherein the heteroatom is attached directly to the conjugated backbone
21) Embodiment #17 wherein the heteroatom is attached to the conjugated backbone via a linker
22) Embodiment #17 wherein the heteroatom is a bromine
23) Embodiment #17 wherein the heteroatom is a chlorine
24) Embodiment #17 wherein the heteroatom is a fluorine
25) Embodiment #17 wherein the heteroatom is an oxygen
26) Embodiment #17 wherein the heteroatom is a sulfur
27) Embodiment #20 wherein the heteroatom is an oxygen
28) Embodiment #27 wherein the oxygen is part of an ether functionality
29) Embodiment #27 wherein the oxygen is part of a hydroxyl functionality
30) Embodiment #20 wherein the heteroatom is a sulfur
31) Embodiments #1-16 wherein the monomer that modifies the energy level of the copolymer contains a nitrile functionality or other electron-withdrawing functionality
32) Embodiment #28 wherein the nitrile is attached directly to the conjugated backbone
33) Embodiment #28 wherein the nitrile is attached to the conjugated backbone via an aryl or alkyl linker
34) Embodiments #1-16 wherein the monomer that modifies the energy level of the copolymer is unsubstituted
35) Embodiments #1-16 wherein the monomer that modifies the energy level of the copolymer is substituted with hydrogen atoms.
36) Embodiments #1-32 wherein the monomer that modifies the energy level of the copolymer is an arylene derivative
37) Embodiments #1-32 wherein the monomer that modifies the energy level of the copolymer is a thiophene derivative
38) Embodiments #1-34 wherein the copolymer has end-group functionality
39) Embodiment #35 wherein the end group functionality contains electron withdrawing substituents
40) Embodiment #35 wherein the end-group functionality contains electron releasing substituents
41) Embodiments #1-16 wherein the monomer that modifies the energy level of the copolymer contains electron withdrawing substituents
42) Embodiments #1-16 wherein the monomer that modifies the energy level of the copolymer contains electron releasing substituents
43) Embodiments #1-39 wherein the copolymer contains vinylene functionality
44) Embodiment # 1-43 wherein the copolymer is oxidized
45) Embodiments # 44 in which the dopant is a molecular halogen.
46) Embodiments #44 in which the dopant is iron or gold trichloride.
47) Embodiments #44 in which the dopant is arsenic pentafluoride.
48) Embodiments #44 in which the dopant is an alkali metal salt of hypochlorite.
49) Embodiments #44 in which the dopant is a protic acid.
50) Embodiments #44 in which the dopant is an organic or carboxylic acid.
51) Embodiments #44 in which the dopant is a nitrosonium salt.
52) Embodiments #44 in which the dopant is an organic oxidant.
53) Embodiments #44 in which the dopant is a hypervalent iodine oxidant.
54) Embodiments #44 in which the dopant is a polymeric oxidant.
55) Embodiments # 1-43 wherein the copolymer is reduced
56) Embodiments # 1-55 that contain a cross-linker
57) Embodiment # 1-56 in which the copolymer comprises a monomer that is a 3-substituted thiophene or one of its derivatives.
58) Embodiment #1-56 in which the copolymer is prepared from a monomer that is a pyrrole or one of its derivatives to form a polypyrrole or derivative thereof.
59) Embodiment # 1-56 in which the copolymer is prepared from a monomer that is an aniline or one of its derivatives
60) Embodiment #1-56 in which the copolymer is prepared from a monomer that is an acetylene or one of its derivatives
61) Embodiment #1-56 in which the copolymer is prepared from a monomer that is a fluorene or one of its derivatives.
62) Embodiment #1-56 in which the copolymer is prepared from a monomer that is an isothianaphthalene or one of its derivatives.
63) Embodiment # 1-62 which is prepared from a monomer which upon polymerization forms a non-conductive polymer
64) Embodiment # 63 in which the monomer is CH₂CH Ar, where Ar=any aryl or functionalized aryl group, isocyanates, ethylene oxides, conjugated dienes.
65) Embodiment # 63 in which the monomers CH₂CHR₁R (where R₁=alkyl, aryl, or alkyl/aryl functionality and R=H, alkyl, Cl, Br, F, OH, ester, acid, or ether), lactam, lactone, siloxanes, and ATRP macroinitiators.
66) A thin film that comprises, along with other components, Embodiments #1-65
67) A solution that comprises, along with a solvent, Embodiments #1-65
68) Embodiment #67 wherein the solution is an “ink” for printed electronics.
69) Embodiment #66 in which the film is prepared by spin casting.
70) Embodiment #66 in which the film is prepared by drop casting.
71) Embodiment #66 in which the film is prepared by dip-coating.
72) Embodiment #66 in which the film is prepared by spray-coating.
73) Embodiment #66 in which the film is prepared by a printing method.
74) Embodiment #66 in which the printing method is ink jet printing.
75) Embodiment #66 in which the printing method is off-set printing.
76) Embodiment #66 in which the printing method is a transfer process.
77) A device that comprises, along with other components, Embodiments #1-76
78) Embodiment #77 wherein the device is an organic light emitting device
79) Embodiment #77 wherein the device is a solar cell
80) Embodiment #77 wherein the device is a non-emitting diode
81) Embodiment #77 wherein the device is a transistor
82) Embodiment #77 wherein the device is a component of a radio frequency identification tag
83) Embodiment #77 wherein the device is a capacitor
84) Methods for forming Embodiments #1-83
85) Use of Embodiment #1-83.
   A preferred embodiment of this invention is a soluble, inherently conductive random copolymer of which is comprised of a 3-alkyl thiophene which imparts solubility and unsubstituted thiophene that modifies the energy levels of the copolymer to suit an end-use application.
   A second preferred embodiment of this invention is a soluble, inherently conductive random copolymer of which is comprised of a 3-alkyl thiophene that imparts solubility and thiophene that reduces the HOMO of the copolymer (as compared to that of the corresponding poly(3-alkyl thiophene)) to suit an end-use application.
   A third preferred embodiment of this invention is a soluble, inherently conductive random copolymer of which is comprised of a 3-alkyl thiophene that imparts solubility and thiophene that reduces the HOMO of the copolymer (as compared to that of the corresponding poly(3-alkyl thiophene)) for use as a p-type semiconductor in a solar cell.
   A fourth preferred embodiment of this invention is a soluble, inherently conductive random copolymer of which is comprised of a 3-alkoxy thiophene that imparts solubility and thiophene that that modifies the energy levels of the copolymer to suit an end-use application.
   A fifth preferred embodiment of this invention is a soluble, inherently conductive random copolymer of which is comprised of a 3-alkoxy thiophene that imparts solubility and thiophene that reduces the HOMO of the copolymer (as compared to that of the corresponding poly(3-alkoxy thiophene)) to suit an end-use application.
   A sixth preferred embodiment of this invention is a soluble, inherently conductive random copolymer of which is comprised of a 3-alkoxy thiophene that imparts solubility and thiophene that reduces the HOMO of the copolymer (as compared to that of the corresponding poly(3-alkoxy thiophene)) for use as a hole injection layer in an organic light emitting diode.
   A seventh preferred embodiment of this invention is a soluble, inherently conductive random copolymer of which is comprised of a 3-alkoxy thiophene that imparts solubility and thiophene that reduces the HOMO of the copolymer (as compared to that of the corresponding poly(3-alkoxy thiophene)) for use as a thin film semiconductor.
   An eighth preferred embodiment of this invention is an oxidized inherently conductive random copolymer of which is comprised of a 3-alkoxy thiophene that imparts solubility and thiophene that reduces the HOMO of the copolymer (as compared to that of the corresponding poly(3-alkoxy thiophene)) for use as a thin film conductor.
   A ninth preferred embodiment of this invention is a soluble, inherently conductive regioregular random copolymer of which is comprised of a 3-alkyl thiophene that imparts solubility and thiophene that modifies the energy levels of the copolymer to suit an end-use application.
   A tenth preferred embodiment of this invention is a soluble, inherently conductive regioregular random copolymer of which is comprised of a 3-alkyl thiophene that imparts solubility and thiophene that reduces the HOMO of the copolymer (as compared to that of the corresponding poly(3-alkyl thiophene)) to suit an end-use application.
   An eleventh preferred embodiment of this invention is a soluble, inherently conductive regioregular random copolymer of which is comprised of a 3-alkyl thiophene which that imparts solubility and thiophene that reduces the HOMO of the copolymer (as compared to that of the corresponding poly(3-alkyl thiophene)) for use as a p-type semiconductor in a solar cell.
   A twelfth preferred embodiment of this invention is a soluble, inherently conductive regioregular random copolymer of which is comprised of a 3-alkoxy thiophene that imparts solubility and thiophene that that modifies the energy levels of the copolymer to suit an end-use application.
   A thirteenth preferred embodiment of this invention is a soluble, inherently conductive regioregular random copolymer of which is comprised of a 3-alkoxy thiophene that imparts solubility and thiophene that reduces the HOMO of the copolymer (as compared to that of the corresponding poly(3-alkoxy thiophene)) to suit an end-use application.
   A fourteenth preferred embodiment of this invention is a soluble, inherently conductive regioregular random copolymer of which is comprised of a 3-alkoxy thiophene that imparts solubility and thiophene that reduces the HOMO of the copolymer (as compared to that of the corresponding poly(3-alkoxy thiophene)) for use as a hole injection layer in an organic light emitting diode.
   A fifteenth preferred embodiment of this invention is a soluble, inherently conductive regioregular random copolymer of which is comprised of a 3-alkoxy thiophene which imparts solubility and thiophene that reduces the HOMO of the copolymer (as compared to that of the corresponding poly(3-alkoxy thiophene)) for use as a thin film semiconductor.
   An sixteenth preferred embodiment of this invention is an oxidized inherently conductive regioregular random copolymer of which is comprised of a 3-alkoxy thiophene that imparts solubility and thiophene that reduces the HOMO of the copolymer (as compared to that of the corresponding poly(3-alkoxy thiophene)) for use as a thin film conductor.
   A seventeenth preferred embodiment of this invention is a soluble, inherently conductive regiorandom random copolymer of which is comprised of a 3-alkyl thiophene that imparts solubility and thiophene that modifies the energy levels of the copolymer to suit an end-use application.
   An eighteenth preferred embodiment of this invention is a soluble, inherently conductive regiorandom random copolymer of which is comprised of a 3-alkyl thiophene that imparts solubility and thiophene that reduces the HOMO of the copolymer (as compared to that of the corresponding poly(3-alkyl thiophene)) to suit an end-use application.
   A nineteenth preferred embodiment of this invention is a soluble, inherently conductive regiorandom random copolymer of which is comprised of a 3-alkyl thiophene that imparts solubility and thiophene that reduces the HOMO of the copolymer (as compared to that of the corresponding poly(3-alkyl thiophene)) for use as a p-type semiconductor in a solar cell.
   A twentieth preferred embodiment of this invention is a soluble, inherently conductive regiorandom random copolymer of which is comprised of a 3-alkoxy thiophene that imparts solubility and thiophene that that modifies the energy levels of the copolymer to suit an end-use application.
   A twenty-first preferred embodiment of this invention is a soluble, inherently conductive regiorandom random copolymer of which is comprised of a 3-alkoxy thiophene that imparts solubility and thiophene that reduces the HOMO of the copolymer (as compared to that of the corresponding poly(3-alkoxy thiophene)) to suit an end-use application.
   A twenty-second preferred embodiment of this invention is a soluble, inherently conductive regiorandom random copolymer of which is comprised of a 3-alkoxy thiophene that imparts solubility and thiophene that reduces the HOMO of the copolymer (as compared to that of the corresponding poly(3-alkoxy thiophene)) for use as a hole injection layer in an organic light emitting diode.
   A twenty-third preferred embodiment of this invention is a soluble, inherently conductive regiorandom random copolymer of which is comprised of a 3-alkoxy thiophene that imparts solubility and thiophene that reduces the HOMO of the copolymer (as compared to that of the corresponding poly(3-alkoxy thiophene)) for use as a thin film semiconductor.
   A twenty-fourth preferred embodiment of this invention is an oxidized inherently conductive regiorandom random copolymer of which is comprised of a 3-alkoxy thiophene that imparts solubility and thiophene that reduces the HOMO of the copolymer (as compared to that of the corresponding poly(3-alkoxy thiophene)) for use as a thin film conductor.

A light emitting diode comprising the composition according to claims 1, 21, or 29 provided hereinbelow.

A thin film semiconductor comprising the composition according to claims 1, 21, or 29 provided hereinbelow.

A thin film conductor comprising the composition according to claims 1, 21, or 29 provided hereinbelow.

A non-emitting diode comprising the composition according to claims 1, 21, or 29 provided hereinbelow.

A transistor comprising the composition according to claims 1, 21, or 29 provided hereinbelow.

An RFID tag comprising the composition according to claims 1, 21, or 29 provided hereinbelow.

A capacitor comprising the composition according to claims 1, 21, or 29 provided hereinbelow.

A method of use comprising use of the compositions of claims 1, 21, or 29 provided hereinbelow in a device, wherein the device is a solar cell, a light emitting diode, a thin film semiconductor, a thin film conductor, a non-emitting diode, a transistor, an RFID tag, or a capacitor.

The composition according to claims 1, 21, or 29 provided hereinbelow, wherein the copolymer is regiorandom.

The composition according to claims 1, 21, or 29 provided hereinbelow, wherein the copolymer is regioregular.

### BRIEF DESCRIPTION OF THE FIGURES

FIG. 1: Schematic diagram of the energy level relationships between the anode (in this case an indium tin oxide-coated glass substrate), the p-type semiconductor, and the n-type semiconductor in an organic solar cell in the (a) ground and (b) excited states.

FIG. 2: A random copolymer of a polythiophene derivative based on a two-component monomer feed. As this is a random copolymer, the proportion of monomers is not necessarily represented within the repeat units as shown even if it is represented over the length of the entire polymer chain. In this figure n can be greater than or equal to 1 and m can be greater than or equal to 1, and X, Y, R₁, R₂, R₃, and R₄ are not particularly limited but can be, for example, —H, —Cl, —Br, —I, —F, alkyl, aryl, alkyl/aryl, alkoxy, aryloxy, substituted alkyl, substituted aryl, substituted alkyl/aryl, substituted alkoxy, substituted aryloxy, functionalized alkyl, functionalized aryl, functionalized alkyl/aryl, functionalized alkoxy, functionalized aryloxy, linear, branched, heteroatomic substituted, oligomeric, polymeric, or contain a halogen, hydroxyl, a carboxylic acid, amide, amine, nitrile, ether, an ester, a thiol, a thioether, and the like.

FIG. 3: A random copolymer of a polythiophene derivative based on a three-component monomer feed. As this is a random copolymer, the proportion of monomers is not necessarily represented within the repeat units as shown even if it is represented over the length of the entire polymer chain. In this figure n can be greater than or equal to 1 and m can be greater than or equal to 1, p>1, and X, Y, R₁, R₂, R₃, R₄, R₅, and R₆ are not particularly limited but can be, for example, —H, —Cl, —Br, —I, —F, alkyl, aryl, alkyl/aryl, alkoxy, aryloxy, substituted alkyl, substituted aryl, substituted alkyl/aryl, substituted alkoxy, substituted aryloxy, functionalized alkyl, functionalized aryl, functionalized alkyl/aryl, functionalized alkoxy, functionalized aryloxy, linear, branched, heteroatomic substituted, oligomeric, polymeric, or contain a halogen, hydroxyl, a carboxylic acid, amide, amine, nitrile, ether, an ester, a thiol, a thioether, and the like.

FIG. 4: A random copolymer of a polythiophene derivative based on a four-component monomer feed. As this is a random copolymer, the proportion of monomers is not necessarily represented within the repeat units as shown even if it is represented over the length of the entire polymer chain. In this figure n can be greater than or equal to 1, m can be greater than or equal to 1, p>1, q>1 and X, Y, R₁, R₂, R₃, R₄, R₅, R₆, R₇, and R₈ are not particularly limited but can be, for example, —H, —Cl, —Br, —I, —F, alkyl, aryl, alkyl/aryl, alkoxy, aryloxy, substituted alkyl, substituted aryl, substituted alkyl/aryl, substituted alkoxy, substituted aryloxy, functionalized alkyl, functionalized aryl, functionalized alkyl/aryl, functionalized alkoxy, functionalized aryloxy, linear, branched, heteroatomic substituted, oligomeric, polymeric, or contain a halogen, hydroxyl, a carboxylic acid, amide, amine, nitrile, ether, an ester, a thiol, a thioether, and the like.

FIG. 5 illustrates regioregular PAT versus regioirregular random copolymer of 3-substituted thiophene and thiophene.

FIG. 6 illustrates three additional polythiophene random copolymers.

FIG. 7 illustrates UV-VIS data for poly(3-hexylthiophene-ran-thiophene) Copolymers (solid state) as function of copolymer ratio.

### DETAILED DESCRIPTION OF THE INVENTION

In practicing the present invention in its various embodiments, the following description of the technical literature and the various components can be used. The references cited throughout the specification including the list at the end are hereby incorporated by reference in their entirety.

Priority provisional patent application Ser. No. 60/661,934 filed Mar. 16, 2005 to Williams et al. is hereby incorporated by reference in its entirety.

Provisional patent application Ser. No. 60/612,640 filed Sep. 24, 2004 to Williams et al. (“HETEROATOMIC REGIOREGULAR POLY(3-SUBSTITUTED THIOPHENES) FOR ELECTROLUMINESCENT DEVICES”), and U.S. Ser. No. 11/234,374 filed Sep. 26, 2005, are hereby incorporated by reference in their entirety including the description of the polymers, the figures, and the claims.

Provisional patent application Ser. No. 60/612,641 filed Sep. 24, 2004 to Williams et al. (“HETEROATOMIC REGIOREGULAR POLY (3-SUBSTITUTED THIOPHENES) FOR PHOTOVOLTAIC CELLS”), and U.S. Ser. No. 11/234,373 filed Sep. 26, 2005 are hereby incorporated by reference in their entirety including the description of the polymers, the figures, and the claims.

Provisional patent application Ser. No. 60/628,202 filed Nov. 17, 2004 to Williams et al. (“HETEROATOMIC REGIOREGULAR POLY (3-SUBSTITUTED THIOPHENES) AS THIN FILM CONDUCTORS IN DIODES WHICH ARE NOT LIGHT EMITTING”), and U.S. Ser. No. 11/274,918 filed Nov. 16, 2005 are hereby incorporated by reference in their entirety including the description of the polymers, the figures, and the claims.

Provisional patent application Ser. No. 60/651,211 filed Feb. 10, 2005 to Williams et al. (“HOLE INJECTION LAYER COMPOSITIONS”), and U.S. Ser. No. 11/350,271 filed Feb. 9, 2006, are hereby incorporated by reference in their entirety including the description of the polymers, the figures, and the claims.

Synthetic methods, doping, and polymer characterization, including regioregular polythiophenes with side groups, is provided in, for example, U.S. Pat. No. 6,602,974 to McCullough et al. and U.S. Pat. No. 6,166,172 to McCullough et al., which are hereby incorporated by reference in their entirety. Additional description can be found in the article, “The Chemistry of Conducting Polythiophenes,” by Richard D. McCullough, Adv. Mater., 10, No. 2, pages 93-116, and references cited therein, which is hereby incorporated by reference in its entirety. Another reference which one skilled in the art can use is the Handbook of Conducting Polymers, 2^{nd} Ed., 1998, Chapter 9, by McCullough et al., “Regioregular, Head-to-Tail Coupled Poly(3-alkylthiophene) and its Derivatives,” pages 225-258, which is hereby incorporated by reference in its entirety.

In addition, electrically conductive polymers are described in The Encyclopedia of Polymer Science and Engineering, Wiley, 1990, pages 298-300, including polyacetylene, poly(p-phenylene), poly(p-phenylene sulfide), polypyrrole, and polythiophene, which is hereby incorporated by reference in its entirety. This reference also describes blending and copolymerization of polymers, including block copolymer formation.

Polythiophenes are described for example in Roncali, J., Chem. Rev., 1992, 92, 711; Schopf et al., Polythiophenes: Electrically Conductive Polymers, Springer: Berlin, 1997.

Inherently Conductive Polymers

Inherently conductive polymers (ICPs) are organic polymers that, due to their conjugated backbone structure, show high electrical conductivities under some conditions (relative to those of traditional polymeric materials). Performance of these materials as a conductor of holes or electrons is increased when they are doped, oxidized or reduced. Upon low oxidation (or reduction) of ICPs, in a process which is frequently referred to as doping, an electron is removed from the top of the valence band (or added to the bottom of the conduction band) creating a radical cation (or polaron). Formation of a polaron creates a partial delocalization over several monomeric units. Upon further oxidation, another electron can be removed from a separate polymer segment, thus yielding two independent polarons. Alternatively, the unpaired electron can be removed to create a dication (or bipolaron). In an applied electric field, both polarons and bipolarons are mobile and can move along the polymer chain by delocalization of double and single bonds. This change in oxidation state results in the formation of new energy states, called bipolarons. The energy levels are accessible to some of the remaining electrons in the valence band, allowing the polymer to function as a conductor. The extent of this conjugated structure is dependent upon the polymer chains to form a planar conformation in the solid state. This is because conjugation from ring-to-ring is dependent upon π-orbital overlap. If a particular ring is twisted out of planarity, the overlap cannot occur and the conjugation band structure can be disrupted. Some minor twisting is not detrimental since the degree of overlap between thiophene rings varies as the cosine of the dihedral angle between them.

Performance of a conjugated polymer as an organic conductor can also be dependant upon the morphology of the polymer in the solid state. Electronic properties can be dependent upon the electrical connectivity and inter-chain charge transport between polymer chains. Pathways for charge transport can be along a polymer chain or between adjacent chains. Transport along a chain can be facilitated by a planar backbone conformation due to the dependence of the charge carrying moiety on the amount of double-bond character between the rings, an indicator of ring planarity. This conduction mechanism between chains can involve either a stacking of planar, polymer segment, called π-stacking, or an inter-chain hopping mechanism in which excitons or electrons can tunnel or “hop” through space or other matrix to another chain that is in proximity to the one that it is leaving. Therefore, a process that can drive ordering of polymer chains in the solid state can help to improve the performance of the conducting polymer. It is known that the absorbance characteristics of thin films of ICPs reflect the increased re-stacking which occurs in the solid state.

To effectively use a conjugated polymer, it is advantageously prepared by a method that allows the removal of organic and ionic impurities from the polymeric matrix. The presence of impurities, notably metal ions for example, in this material may have serious deleterious effects on the performance of resulting photovoltaic cells. These effects include charge localization or trapping, quenching of the exciton, reduction of charge mobility, interfacial morphology effects such as phase separation, and oxidation or reduction of the polymer into an uncharacterized conductive state which is not suitable for a particular application. There are several methods by which impurities may be removed from a conjugated polymer. Most of these are facilitated by the ability to dissolve the polymer in common organic and polar solvents. Unfortunately, poly(thiophene) is, essentially, insoluble.

Manipulation of Band Gap/Energy Levels

Recently there has been much interest in the incorporation of ICPs into organic electronics devices [see, e.g. Braun, D., Materials Today, 2002, June, 32-39., Dimitrakopoulos, IBM J. Res. & Dev., 2001, 45, No. 1, 11-27 and references cited therein]. These applications function via the exploitation of the electrical and optical properties of the ICPs that arise from their (a) conjugated structure, (b) functionality, and (c) conformation (in solution) or morphology (in the solid state).

In applications such as polymer-based solar cells, polymer light emitting diodes, organic transistors, or other organic circuitry the flow of electrons and positive conductors (i.e. “holes”) is dictated by the relative energy gradient of the conduction and valence bands within the components. Therefore, suitable ICPs for a given application are selected for the values of their energy band levels which may be suitably approximated through analysis of ionization potential (as measured by cyclic voltammetry) Micaroni, L et al., J. Solid State Electrochem., 2002, 7, 55-59 and references sited therein) and band gap (as determined by UV/Vis/NIR spectroscopy as described in Richard D. McCullough, Adv. Mater., 1998, 10, No. 2, pages 93-116, and references cited therein).

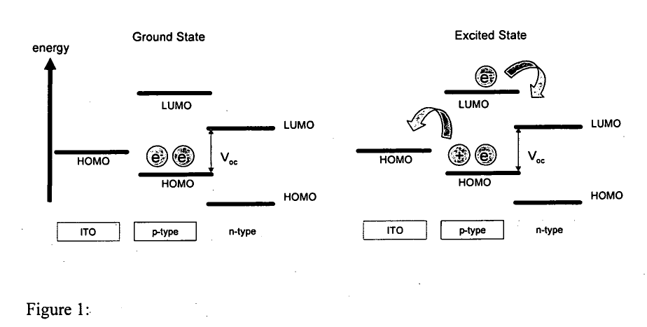

For example, in the case of photovoltaic or solar cells, the device typically comprises at least four components, two of which are electrodes. One component is a transparent first electrode such as indium tin oxide coated onto plastic or glass which functions as a charge carrier, typically the anode, and allows ambient light to enter the device. Another component is a second electrode which can be made of a metal such as calcium or aluminum. In some cases, this metal may be coated onto a supporting surface such as a plastic or glass sheet. This second electrode also carries current. Between these electrodes are either discrete layers or a mixture of p- and n-type semiconductors, the third and fourth components. The p-type material can be called the primary light harvesting component or layer. This material absorbs a photon of a particular energy and generates an excited state in which an electron is promoted to an energy state known as the Lowest Unoccupied Molecular Orbital (or LUMO, see FIG. 1), leaving a positive charge or “hole” in the ground state energy level (a.k.a. Highest Occupied Molecular Orbital or HOMO). As known in the art, this is known as exciton formation. The exciton diffuses to a junction between p-type and n-type material, creating a charge separation or dissociation of the exciton. The electron and “hole” charges are conducted through the n-type and p-type materials respectively, to the electrodes resulting in the flow of electric current out of the cell. The direction of flow for charge carriers at an interface is dictated by the potential gradient wherein an electron will flow toward a more stable, or lower, half-filled or vacant energy state and a “hole” will flow to a higher, half-filled or fully occupied energy state as it really represents the absence of an electron, and is consistent with moving along the negative potential gradient of an electron.

In the case of polymer-based light emitting diodes, it has been shown (see, for example, Shinar, J. Organic Light-Emitting Devices, Springer-Verlag New-York, Inc. 2004 and references incorporated therein) that matching the energy levels of the ICP to that of the other components of the device is important for device performance. Therefore, many have sought to control the energy of the HOMO, the LUMO, as well as the difference of these energy levels (a.k.a. “band gap,” which also corresponds to the π-π* transition energy as observed through UV/Vis/NIR spectroscopy) through manipulation of the back-bone structure of the conductive polymer (see, for example, Roncali, J., Chem. Rev. 1997, 97, 173., Winder, C.; Sariciftci, N. S., J. Mater. Chem., 2004, 14, 1077, and Colladet, K.; Nicolas, M.; Goris, L.; Lutsen, L.; Vanderzande, D., Thin Solid Films, 2004, 7-11, 451. as well as in the references incorporated herein).

Poly(3-Subtituted Thiophenes)

Some poly(3-substituted thiophenes) with alkyl, aryl, and alkyl-aryl substituents are soluble in common organic solvents such as toluene and xylene. These materials share a common conjugated π-electron band structure, similar to that of poly(thiophene) that make them suitable p-type conductors for electronic applications, but due to their solubility they are much easier to process and purify than poly(thiophene). These materials can be made as oligomer chains such as (3-alkythiophene)ₙ, (3-arylthiophene)ₙ, or (3alkyl/arylthiophene)ₙ in which n is the number of repeat units with a value of 2-10 for oligomers or as polymers in which n=11-350 or higher, but for these materials n most typically has a value of 50-200.

However, adding a 3-substituent to the thiophene ring makes the thiophene repeat unit asymmetrical. Polymerization of a 3-substituted thiophene by conventional methods results in 2,5′-couplings, but also in 2,2′- and 5,5′-couplings. The presence of 2,2′-couplings or a mixture of 2,5′-, 2,2′- and 5,5′-couplings results in steric interactions between 3-substituents on adjacent thiophene rings which can create a torsional strain. The rings then rotate out of a planarity to another, more thermodynamically stable, conformation which minimizes the steric interactions from such couplings. This new conformation can include structures where π-overlap is significantly reduced. This results in a reduction in π-overlap between adjacent rings, and if severe enough, the net conjugation length decreases and with it the conjugated band structure of the polymer. The combination of these effects impairs the performance of electronic devices made from these regio-randomly coupled poly(3-substituted thiophenes).

Regioregular Poly(3-Substituted Thiophenes)

Materials with superior π-conjugation, electrical communication, and solid state morphology can be prepared by using regiospecific chemical coupling methods that produce greater than 95% 2,5′-couplings of poly(3-substituted thiophenes) with alkyl substituents. These materials have been prepared via the use of a Kumada-type nickel-catalyzed coupling of a 2-bromo-5-magnesiobromo-3-substituted thiophene as well as by the zinc coupling of a 2-bromo-5-thienylzinc halide which has been reported by Reike. A more practical preparative synthesis of a regio-regular poly(3-substituted thiophene) with alkyl substituents was carried out by the Grignard metathesis of a 2,5-dibromo-3-alkylthiophene, followed by nickel cross coupling.

Like regio-random poly(3-substituted thiophenes) with alkyl, aryl, and alkyl/aryl substituents, regio-regular poly(3-substituted thiophenes) with alkyl, aryl, and alkyl/aryl substituents are soluble in common organic solvents and demonstrate enhanced processability in applications by deposition methods such as spin-coating, drop casting, dip coating, spraying, and printing techniques (such as ink-jetting, off-setting, and transfer-coating). Therefore, these materials can be better processed in large-area formats when compared to regio-random poly(3-substituted thiophenes). Furthermore, because of the homogeneity of their 2,5′-ring-to-ring couplings, they exhibit evidence of substantial π-conjugation and high extinction coefficients for the absorption of visible light corresponding to the π-π* absorption for these materials. This absorption determines the quality of the conducting band structure which may be utilized when a regioregular poly(3-substituted thiophene) with alkyl, aryl, or alkyl/aryl substituents is used in an organic electronic device and, therefore, determines the efficiency and performance of the device.

Another benefit of the regio-regularity of these materials is that they can self-assemble in the solid state and form well-ordered structures. These structures tend to juxtapose thiophene rings systems through a π-stacking motif and allow for improved inter-chain charge transport through this bonding arrangement between separate polymers, enhancing the conductive properties when compared to regio-random polymers. Therefore, one can recognize a morphological benefit to these materials.

As is the case with the use poly(thiophene) it has been shown that some poly(3-substituted thiophenes) with alkyl, aryl, and alkyl-aryl substituents are soluble in common organic solvents such as toluene and xylene. These materials share a common conjugated π-electron band structure, similar to that of poly(thiophene) that make them suitable p-type conductors for electronic applications, but due to their solubility they are much easier to process and purify than poly(thiophene). These materials can be made as oligomer chains such as (3-alkythiophene)ₙ, (3-arylthiophene)ₙ, or (3alkyl/arylthiophene)ₙ, in which n is the number of repeat units with a value of 2-10 or as polymers in which n=11-350 or higher, but for these materials n most typically has a value of 50-200.

Substituent Effects

Since the electronic properties of an inherently conductive polymer arise from the conjugated band structure of the polymer backbone, any factors that increase or decrease the electron density within the backbone π-structure directly affect the band gap and energy levels of the ICP. Therefore, substituents that are attached to the backbone and contain electron withdrawing substituents will reduce the electron density of the conjugated backbone and deepen the HOMO of the polymer. Substituents that are attached to the backbone and contain electron releasing functionality will have the opposite effect. The nature of the effects of substitution is known to any skilled in the art and is well documented in general texts on organic chemistry March, J. Advanced Organic Chemistry, third edition, John Wiley & Sons, New-York, Inc. 1985 and references incorporated therein). In both cases, the magnitude of the change in energy levels of the polymer depend upon the specific functionality of the substituent, the proximity or nature of attachment of the functionality to the conjugated backbone, as well as the presence of other functional characteristics within the polymer.

In the case of poly(3-alkyl thiophenes), the alkyl substituents that are typically included to increase solubility have an electron releasing effect, raising the HOMO of the polymer relative to that of poly(thiophene). It has been shown, for example, that a fluorine substituent either as a component of 3-substituent or as the 4-substituent of a poly(thiophene) will withdraw electrons from a poly(thiophene) homopolymer, lowering the HOMO of the conductive polymer (US 2003/0062509 A1 and US 2003/0047720 A1). In other work (Provisional patent application Ser. No. 60/612,641 filed Sep. 24, 2004 to Williams et al. (“HETEROATOMIC REGIOREGULAR POLY (3-SUBSTITUTED THIOPHENES) FOR PHOTOVOLTAIC CELLS”) is hereby incorporated by reference in its entirety including the description of the polymers, the figures, and the claims. Provisional patent application Ser. No. 60/628,202 filed Nov. 17, 2004 to Williams et al. (“HETEROATOMIC REGIOREGULAR POLY (3-SUBSTITUTED THIOPHENES) AS THIN FILM CONDUCTORS IN DIODES WHICH ARE NOT LIGHT EMITTING”) is hereby incorporated by reference in its entirety including the description of the polymers, the figures, and the claims). It can be seen that alkoxy substitutents on the 3-position may be used to decrease the band gap of a regioregular poly(3-substituted thiophene). In each of these cases, the manipulation of the energy levels has been accomplished by modification of the backbone of a homopolymer. In many instances, it is important to incorporate a particular functionality into an ICP to impart a specific property. For example, the alkyl substituent of a poly(3 hexylthiophene) is included to make the polymer soluble in common organic solvents. However, for an application in which a deep HOMO is required, this electron-releasing functionality actually imparts the opposite of the desired electronic effect.

Therefore, a flexible synthetic method through which electronic, optical, and physical properties of the ICP may be balanced and tuned to offer a material that satisfies diverse performance requirements offers a real advantage in organic device development.

Random Copolymers

In the case of regioregular poly(3-substituted thiophenes), McCullough et al. (McCullough, R. D.; Jayaraman, M. J. Chem. Soc., Chem. Commun., 1995, 135.) demonstrated that regioregular, random copolymers could be in some cases prepared by mixing reactive precursors of poly(3-alkyl thiophenes). The work demonstrated that in some cases the properties of these polymers could be tuned based on the relative feed ratio of suitably substituted monomers. An increase in the incorporation of a given co-monomer in some cases would increase it's electronic and solvation characteristics, by virtue of it's substitution, to the properties of the corresponding copolymer. Since the 1995 McCullough paper, however, improved synthetic methods have been developed including the GRIM polymerization. See, for example, U.S. Pat. No. 6,166,172 to McCullough et al. Copolymerization with GRIM methods can impact the polymer microstructure. Another synthetic method is described in, for example, US patent publication 2005/0080219 (Koller et al.).

In this invention, in its various embodiments, use of an approach is described wherein the electronic and optical properties of an ICP is systematically modified so as to optimize the balance of properties to suit end use in an electronic device.

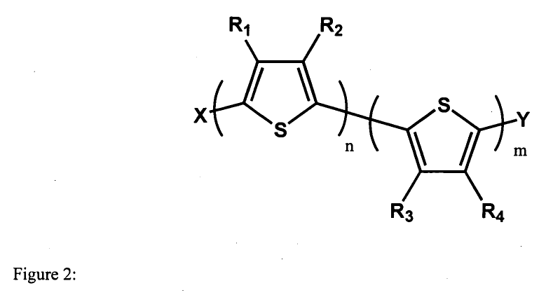

In the case of a photovoltaic or solar cell, for example, the intent would be maximize the potential difference, as indicated by V_{OC} of a manufactured photovoltaic device, between the LUMO of the n-type semiconductor and the HOMO of the p-type semiconductor (as illustrated in FIG. 1) while maintaining the solubility and polarity of the p-type semiconductor such that these characteristics are similar to those of high-performing p-type semi conductors such as regioregular poly(3-hexylthiophene). In one embodiment, this may be accomplished by the formation of a regioregular random copolymer that comprises 3-hexylthiophene and thiophene (see FIG. 2 wherein R₁, R₂, and R₃ are “H—” and R₄ is a C₆H₁₃ (hexyl) group) in a manner that optimizes the balance between maximized HOMO energy level, solubility, and polarity for the copolymer as it compares to the corresponding homopolymer of poly(3-hexylthiophene) (Table 1). The thiophene component was chosen as a comonomer due to its lack of an electron-releasing functionality and when incorporated into a poly(3-heyxlthiophene) homopolymer shall serve to reduce the HOMO by decreasing the amount of electron-releasing character of the 3-hexylthiophene monomeric units.

If a comonomer is used, such as unsubstituted thiophene, which reduces the solubility of the copolymer, then the other comonomer can be selected to have relatively high solubility to compensate and retain good processability. For example, a hexyl-substituted monomer can be replaced with a branched alkyl-substituted monomer such as ethylhexyl.

In the case of the hole injection layer of a polymer-based light emitting polymer, the HOMO of regioregular poly(3-(1,4,7-trioxaoctyl)thiophene) may be reduced in order to increase the energy level gradient of the ITO transparent anode and the light emitting polymer by the formation of a regioregular random copolymer that comprises 3-(1,4,7-trioxaoctyl)thiophene and thiophene in a ratio that optimizes that balance between energy level and solubility for the copolymer as it compares to the corresponding homopolymer. The use of thiophene is analogous to the above example.

In the case of an organic field effect transistor, the invention can maximize the mobility of the p-type semiconductor while maintaining the solubility and polarity such that these characteristics are similar to those of high-performing p-type semiconductors such as regioregular poly(3-hexyl thiophene). In one embodiment, this may be accomplished by the formation of a regioregular random copolymer that comprises 3-hexyl thiophene and 3-methyl thiophene (see FIG. 2 wherein R₁ and R₃ are “H—”, R₃ is a methyl group, and R₄ is a hexyl group and) in a manner that optimizes the balance between mobility solubility, and polarity for the copolymer as it compares to the corresponding homopolymer.

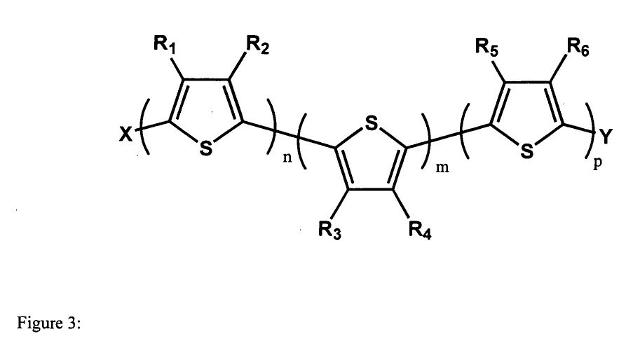

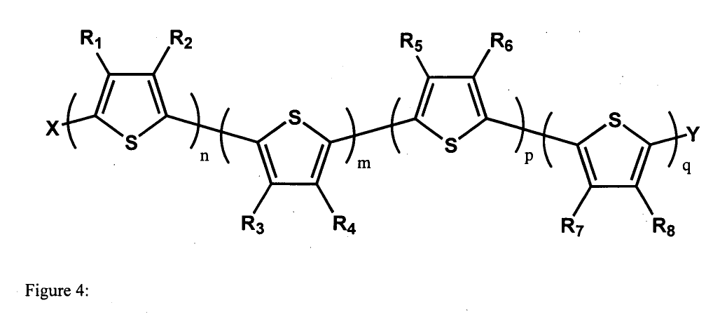

In other embodiments the number of comonomers could be increased beyond two, three, or higher (see FIGS. 3 and 4). This may be important in applications in which the addition of a co-monomer, such as as the strongly electron-withdrawing 3-cyanothiophene functionality, could have a large, negative impact on solubility. The addition of a mixture of co-monomers may be required to balance electronic and physical characteristics.

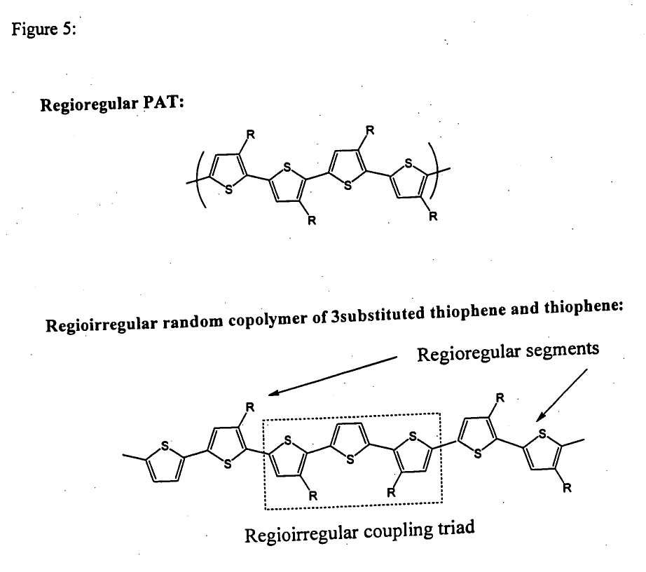

The present invention is not limited by theory, but the copolymerization of a non-substituted thiophene may impact the amount of regioregular character in the copolymer particularly for a GRIM polymerization. For example, the non-substituted thiophene monomer can result in a loss of the regioregular character in the thiophene sections of the chain. For example, it can fall below 90%, or even fall below 80% or even fall below 70%, or even fall below 60%, or even fall below 50%, so that the copolymer is no longer regioregular. NMR can be used to determine the amount of regioregularity. The incorporation of a small amount of a different regioisomeric 3-substituted monomer into the random copolymers can deepen the HOMO of the resulting polymer by introducing twists or kinks into the polymer chain, reducing the effective conjugation of the polymer and hence its optical and electronic properties. The HOMO, for example, can be observed in CV methods to deepen by as much as 350 meV as compared to a P3HT homopolymer. Photovoltaic devices constructed with these random copolymers can show enhanced open-circuit voltages—an indication of a deepened HOMO. In addition, augmented optical absorption by structural differences can also be observed in the UV-Vis-NIR spectra of these materials. FIG. 5 illustrates a regioirregular coupling triad.

The random copolymer can make up the entire polymer chain, or the polymer chain can also comprise units, oligomers, or polymer segments which do not comprise the random copolymer. For example, block copolymers can be produced which comprise the random copolymer.

If the GRIM polymerization method is used with two monomers, the two monomers can be subjected to metathesis with Grignard reagent either (i) together in the same reactor, or (ii) separately or independently in different reactors. The separate reactor can be useful when, for example, one monomer should be subjected to metathesis and Grignard reagent under different conditions than the other monomer. For example, use of a thiophene monomer such as a 3-cyanothiophene compound would generally mean use of different metathesis reaction conditions.

### EMBODIMENTS

In this invention, suitable examples of ICPs include, but are not limited to, regioregular poly(3-substituted thiophene) and its derivatives, poly(thiophene) or a poly(thiophene) derivative, a poly(pyrrole) or a poly(pyrrole) derivative, a poly(aniline) or poly(aniline) derivatives, a poly(phenylene vinylene) or poly(phenylene vinylene) derivatives, a poly(thienylene vinylene) or poly(thienylene vinylene) derivatives, poly(bis-thienylene vinylene) or a poly(bis-thienylene vinylene) derivatives, a poly(acetylene) or poly(acetylene) derivative, a poly(fluorene) or poly(fluorene) derivatives, a poly(arylene) or poly(arylene) derivatives, or a poly(isothianaphthalene) or poly(isothianaphthalene) derivatives.

Derivatives of a polymer can be modified polymers, such as a poly(3-substituted thiophene), which retain an essential backbone structure of a base polymer but are modified structurally over the base polymer. Derivatives can be grouped together with the base polymer to form a related family of polymers. The derivatives generally retain properties such as electrical conductivity of the base polymer.

U.S. Pat. No. 6,824,706 and US Patent Publication No. 2004/0119049 (Merck) also describe charge transport materials which can be used in the present invention, and these references are hereby incorporated by reference in their entirety.

In this invention, a copolymer of these materials can be block-, alternating-, graft- and random-copolymers of which incorporate one or more of the materials defined as an inherently conductive polymer (ICP) such as a regioregular poly(3-substituted thiophene) or its derivatives, poly(thiophene) or poly(thiophene) derivatives, a poly(pyrrole) or poly(pyrrole) derivatives, a poly(aniline) or poly(aniline) derivatives, a poly(phenylene vinylene) or poly(phenylene vinylene) derivatives, a poly(thienylene vinylene) or poly(thienylene vinylene) derivatives, poly(bis-thienylene vinylene) or poly(bis-thienylene vinylene) derivatives, a poly(acetylene) or poly(acetylene) derivatives, a poly(fluorene) or poly(fluorene) derivatives, a poly(arylene) or poly(arylene) derivatives, or a poly(isothianaphthalene) or poly(isothianaphthalene) derivatives as well as segments composed of polymers built from monomers such as CH₂CH Ar, where Ar=any aryl or functionalized aryl group, isocyanates, ethylene oxides, conjugated dienes, CH₂CHR₁R (where R₁=alkyl, aryl, or alkyl/aryl functionality and R=H, alkyl, Cl, Br, F, OH, ester, acid, or ether), lactam, lactone, siloxanes, and ATRP macroinitiators.

In this invention, a copolymer is also provided as random or well-defined copolymer of an inherently conductive polymer (ICP) such as a regioregular poly(3-substituted thiophene) or its derivatives, poly(thiophene) or a poly(thiophene) derivative, a poly(pyrrole) or a poly(pyrrole) derivative, a poly(aniline) or poly(aniline) derivative, a poly(phenylene vinylene) or poly(phenylene vinylene derivative), a poly(thienylene vinylene) or poly(thienylene vinylene derivative), a poly(acetylene) or poly(acetylene) derivative, a poly(fluorene) or poly(fluorene) derivative, a poly(arylene) or poly(arylene) derivative, or a poly(isothianaphthalene) or poly(isothianaphthalene) derivative as well as a block comprised of one or more functionalized ICP polymer or oligomer copolymer with random or well-defined copolymer comprised of one or more conjugated units. In the case of regioregular copolymer of thiophene derivatives, the comonomers may contain alkyl, aryl, alkyl-aryl, alkoxy, aryloxy, fluoro, cyano, or a substituted alkyl, aryl, or alkyl-aryl functionalities in either the 3- or 4-position of the thiophene ring.

Photovoltaic devices can be prepared, wherein one device is prepared with use of the copolymers according to the invention, and another is prepared with use of a polythiophene homopolymer. Using the copolymers, the open circuit voltage can be increased by 10% or more, or in some cases, by 20% or more, and in some cases by 30% or more, and still further by 40% or more.

The invention is further described with use of the following non-limiting working examples.

### EXAMPLES

### Example 1

Poly(3-hexylthiophene-ran-thiophene) 50:50 (x) co-metathesis variation was prepared by dissolving 2,5-dibromo-3-hexylthiophene (x) (2.00 g, 8.3 mmol) and 2,5-dibromothiophene (x) (2.69 g, 8.3 mmol) in distilled THF (165 mL) in a nitrogen purged three-necked flask. The flask was equipped for reflux, nitrogen purge, and magnetic stirring. To the reaction vessel tert-butylmagnesim chloride (9.99 mL, 15.0 mmol) was added via syringe. The reaction was heated to reflux for one hour, and then allowed to cool to ambient temperature. Ni(dppp)Cl₂ (67.6 mg, 0.12 mmol) was added to the solution and stirred with reflux for 3 hours. The polymer was precipitated in methanol (280 mL) and several drops of conc. HCl were added to facilitate polymer aggregation. The mixture was filtered and the solid polymer was stirred in methanol (100 mL) and refiltered. The material was stirred with water (48 mL) and aqueous HCl (27 mL) solution at ˜55° C. for one hour and filtered. The filter cake was rinsed with water and isopropyl alcohol. The solid was isolated and stirred with water (200 mL) at ˜55° C., filtered and rinsed with water. The polymer was dried under vacuum to afford a dark colored powder.

The polymer was extracted with methanol then with chloroform. The chloroform fraction was concentrated under reduced pressure (˜35 torr) and cast on a Teflon pan. The film was allowed to dry to yield a black solid (0.35 g, 17%). Cyclic voltametry: Vox (onset)=0.69 V (Ag/AgCl) and a WF=−5.09 eV; Mn=6,660 PDI=8.3 λmax=508.1 nm. Mn data was collected prior to methanol and chloroform extractions.

### Example 2

Poly(3-(2-ethylhexyl)thiophene-ran-thiophene) 50:50 (x) Co-methathesis variation. was prepared by dissolving 2,5-dibromo-3-ethylhexylthiophene (x) (4.39 g, 12.4 mmol) and 2,5-dibromothiophene (x) (3.00 g, 12.4 mmol) in distilled THF (124 mL) in a nitrogen purged three-necked flask. The flask was equipped for reflux, nitrogen purge, and magnetic stirring. To the reaction vessel tert-butylmagnesim chloride (15.7 mL, 23.5 mmol) was added via syringe. The reaction was heated to reflux for one hour, and then allowed to cool to ambient temperature. Ni(dppp)Cl₂ (0.100 mg, 0.18 mmol) was added to the solution and stirred with reflux for 3 hours. The polymer was precipitated in methanol (225 mL) and several drops of conc. HCl were added to facilitate polymer aggregation. The mixture was filtered and the solid polymer was stirred in methanol (160 mL) and refiltered. The polymer was stirred in water (325 mL) overnight and filtered. The material was stirred with water (80 mL) and aqueous HCl (45 mL) solution at ˜55° C. for one hour and filtered. The filter cake was rinsed with water and isopropyl alcohol. The solid was isolated and stirred with water (325 mL) at ˜55° C., filtered and rinsed with water. The polymer was dried under vacuum to afford a dark colored powder.

The polymer was extracted with methanol then with chloroform. The chloroform fraction was concentrated under reduced pressure (˜35 torr) and cast on a Teflon pan. The film was allowed to dry to yield a black solid (1.4 g, 41%). Cyclic voltametry: Vox (onset)=0.73 V (Ag/AgCl), WF=−5.09 eV; Mn=5,530 PDI=2.0 λmax=501

### Example 3

Synthesis of 3-[2-(methoxyethoxy)ethoxy]thiophene-ran-thiophene (P3MEET-TH). Co-metathesis variation. In a typical experiment, to an oven-dried 100 mL, three-neck flask equipped with a magnetic stir bar and a reflux condenser, 2,5-dibromo-3-[2-(methoxyethoxy)-ethoxy]thiophene (1.06 g; 3 mmol), 2,5-dibromothiophene (0.73 g; 3 mmol), 60 mL THF, and 0.1 mL dodecane, as internal GC standard, were added via syringe. Cyclohexylmagnesium bromide (3 mL sol. 2.0 mol/L in diethyl ether; 6 mmol) was added and the mixture was heated to reflux for one hour. The flask was removed from the oil bath and the mixture was allowed to cool to room temperature. GC analysis of the quenched sample showed complete metathesis of both co-monomers, with a 66/34 ratio of 5-bromo-3-[2-(methoxyethoxy)ethoxy]thiophene vs. 2-bromo-3-[2-(methoxyethoxy)ethoxy]thiophene. 1,3-Bis(diphenylphosphino)propane]nickel dichloride (0.1 g; 0.09 mmol) was added and the reaction mixture was stirred at reflux for 3 hours. The mixture was poured into water (250 mL) and filtered through a 5μ Millipore filter. The polymer was washed on the filter with 1.6% aqueous hydrochloric acid solution, then with water and methanol. Soxlet extractions were performed with hexane and 2-propanol and the polymer was dried in vacuum, affording 1.2 g (72% yield) solid 50:50 copolymer with Mₙ=6020 and PDI=1.43. Cyclic voltammetry data (SCE); Vox(onset)=0.49 V; HOMO=−4.85 eV. HOMO level can be equated with oxidation potential as determined by cyclic volatametry.

### Example 4

Synthesis of 3-[2-(methoxyethoxy)ethoxy]thiophene-ran-thiophene (P3MEET-TH). Independent monomer metathesis variation. To an oven-dried 100 mL, three-neck flask equipped with a magnetic stir bar and a reflux condenser, 2,5-dibromo-3-[2-(methoxyethoxy)-ethoxy]thiophene (0.88 g; 2.5 mmol), 25 mL THF, and 0.1 mL dodacane, as internal GC standard, were added via syringe. Mesitylmagnesium bromide (2.5 mL sol. 1.0 mol/L in diethyl ether; 2.5 mmol) was added and the mixture was heated to reflux for 1.5 hours. Then, the flask was removed from the oil bath and the mixture let to cool to room temperature. GC analysis of the quenched sample showed 88% metathesis of monomer, with a 91.6/8.4 ratio of 5-bromo-3-[2-(methoxyethoxy)ethoxy]thiophene vs. 2-bromo-3-[2-(methoxyethoxy)-ethoxy]thiophene. To another 100 mL, three-neck flask equipped with a magnetic stir bar and a reflux condenser, 2,5-dibromothiophene (0.605 g; 2.5 mmol), 25 mL THF, and 0.1 mL dodecane, as internal GC standard, were added via syringe. Mesitylmagnesium bromide (2.5 mL sol. 1.0 mol/L in diethyl ether; 2.5 mmol) was added and the mixture was heated to reflux for 3.5 hours. The flask was removed from the oil bath and the mixture was allowed to cool to room temperature. GC analysis of the quenched sample showed 57% metathesis of starting dibromide. The solution was then transferred via canula over the reaction mixture from first flask, and [1,3-bis(diphenylphosphino)-propane]nickel dichloride (0.041; 0.075 mmol) was added and the reaction mixture was stirred at reflux for 3 hours. The mixture was poured into hexane (200 mL) and filtered. The polymer was washed on the filter with 1.6% aqueous hydrochloric acid solution, then with water and methanol. Soxhlett extractions were performed with hexane and 2-propanol and the polymer was dried in vacuum, affording 0.6 g (42% yield) solid 60:40 2,5-dibromo-3-[2-(methoxyethoxy)ethoxy]thiophene-ran-thiophene copolymer with Mₙ=3930 and PDI=1.36. Cyclic voltammetry data (SCE); Vox(onset)=0.773 V; HOMO=−5.133 eV.

Table 1 provides data for polymers and copolymers prepared by methods substantially analogous according to working example 1.

TABLE 1
Work Function Tunability of random copolymers with
% thiophene composition

| % Thiophene | Vox Onset (V)^{a} | Work Function (eV)^{b} |
|---|---|---|
| 70.00 | 0.83 | −5.23 |
| 50.00 | 0.69 | −5.09 |
| 25.00 | 0.58 | −4.98 |
| 0.00 | 0.55 | −4.95 |

^{a}vs. SCE
^{b}Micaroni, L.; Nart, F. C.; Hümmelgen, I. A. J. Solid State Electrochem 2002, 7, 55-59

### Example 5

A Heterojunction polymer-based photovoltaic cell was made using Poly(3-(2-ethylhexyl)thiophene-ran-thiophene) 50:50. A photovoltaic device was prepared with use of patterned indium tin oxide (ITO, anode) glass substrate, thin layer of poly(3,4-ethylenedioxythiophene) doped with polystyrene sulfonic acid (PEDOT:PSS, Bayer AG), thin layer of the thiophene copolymer, and methanofullerence [6,6]-phenyl C61-butyric acid methyl ester (PCBM) blend, and Ca cathode with an Al protective layer on the top. The patterned ITO glass substrates used in this invention were cleaned with hot water and organic solvents (acetone and alcohol) in an ultrasonic bath and treated with oxygen plasma before the PEDOT:PSS water solution was spin coated on the top. The film was dried overnight under vacuum at 100° C. The thickness of PEDOT:PSS film was controlled at about 100 nm. Tapping mode atomic force microscopy (TMAFM) height image shows that PEDOT:PSS layer can planarize the ITO anode. The 1:1 (weight) Poly(3-(2-ethylhexyl)thiophene-ran-thiophene):PCBM blend was next spin-coated on top of the PEDOT:PSS film from organic solvent (no damage to PEDOT:PSS film) to give an 100 nm thick film. Then the film was annealed at 100° C. for 5 mins in glove box. TMAFM height and phase images indicate this blend can microphase separate into bicontinuous bulky heterojunction. Next, the 40 nm Ca was thermally evaporated onto the active layer through a shadow mask, followed by deposition of a 200 nm Al protective film. Under same preparation and testing conditions, this ICP system showed 42% higher open circuit voltage (V_{OC}) than that of regioregular poly(3-hexylthiophene) (0.52 versus 0.74). V_{OC} values were averaged from 8 devices with less than 5% deviation.

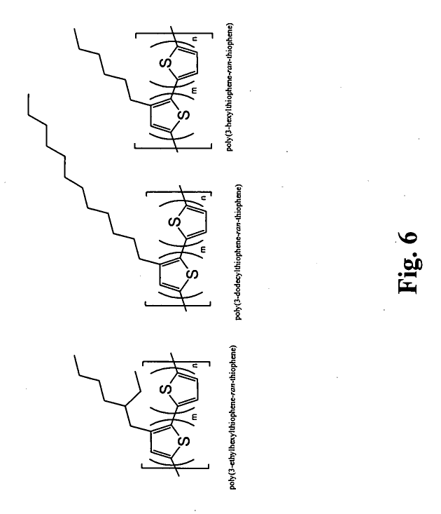

FIG. 6 illustrates three additional polythiophene random copolymers which were prepared showing the advantageous technical effects described herein.

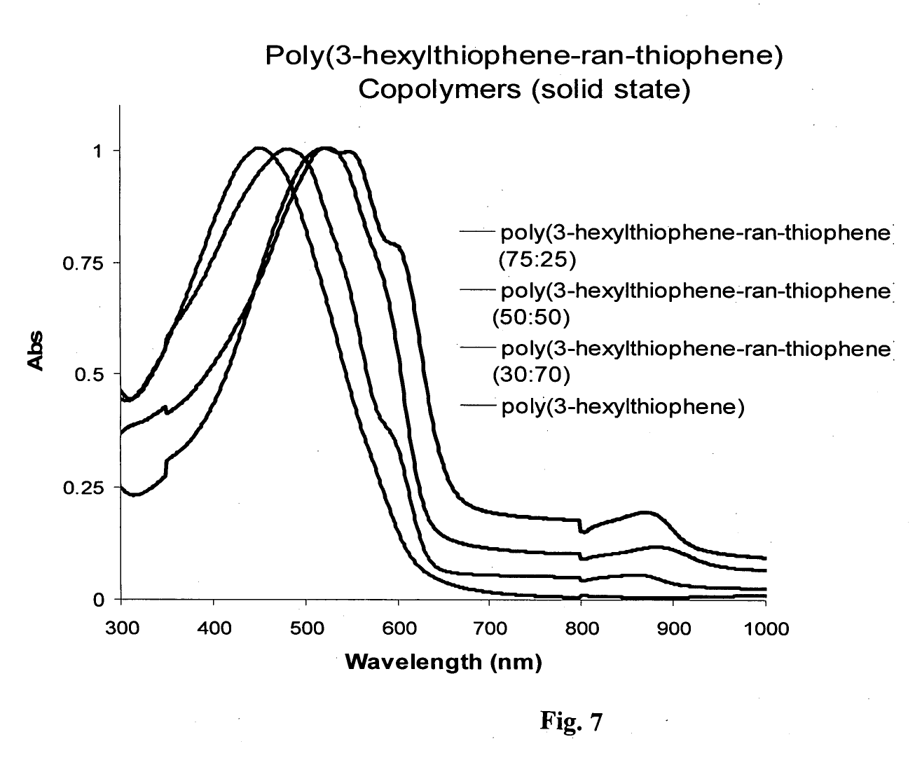

FIG. 7 illustrates UV-VIS data for poly(3-hexylthiophene-ran-thiophene) Copolymers (solid state) as function of copolymer ratio showing the advantageous technical effects described herein.

What is clamed is:

1. A composition comprising a soluble, inherently conductive random copolymer comprising at least one 3-alkyl thiophene repeat unit and sufficient amount of unsubstituted thiophene repeat unit to provide the copolymer with a work function of −4.98 eV or lower and with a Vox onset of 0.58 V (SCE) or higher.

2. The composition according to claim 1, wherein the work function is −5.09 eV or lower.

3. The composition according to claim 1, wherein the work function is −5.23 eV or lower.

4. The composition according to claim 1, wherein the Vox Onset is at least 0.69 V.

5. The composition according to claim 1, wherein the Vox Onset is at least 0.83 V.

6. The composition according to claim 1, wherein the Vox Onset is at least 0.69 V and the work function is at least −5.09 eV or lower.

7. The composition according to claim 1, wherein the Vox Onset is at least 0.83 V and the work function is at least −5.23 eV or lower.

8. The composition according to claim 1, wherein the alkyl group has 11 or fewer carbons.

9. The composition according to claim 1, wherein the composition comprises at least two 3-alkyl thiophene repeat units.

10. The composition according to claim 1, wherein the composition comprises at least three 3-alkyl thiophene repeat units.

11. The composition according to claim 1, wherein the amount of unsubstituted thiophene repeat unit is at least about 25 mole % with respect to monomer repeat units.

12. The composition according to claim 1, wherein the amount of unsubstituted thiophene repeat unit is at least about 50 mole % with respect to monomer repeat units.

13. The composition according to claim 1, wherein the amount of unsubstituted thiophene repeat unit is at least about 70 mole % with respect to monomer repeat units.

14. The composition according to claim 6, wherein the amount of thiophene repeat unit is at least about 25 mole % with respect to monomer repeat units.

15. The composition according to claim 6, wherein the amount of thiophene repeat unit is at least about 50 mole % with respect to monomer repeat units.

16. The composition according to claim 6, wherein the amount of thiophene repeat unit is at least about 70 mole % with respect to monomer repeat units.

17. The composition according to claim 7, wherein the amount of thiophene repeat unit is at least about 25 mole % with respect to monomer repeat units.

18. The composition according to claim 7, wherein the amount of thiophene repeat unit is at least about 50 mole % with respect to monomer repeat units.

19. The composition according to claim 7, wherein the amount of thiophene repeat unit is at least about 70 mole % with respect to monomer repeat units.

20. The composition according to claim 19, wherein the alkyl group is linear and has 11 or less carbon atoms.

21. A composition comprising a soluble, inherently conductive random copolymer comprising at least one 3-substituted thiophene repeat unit and sufficient amount of unsubstituted thiophene repeat unit to provide the copolymer with a work function of −4.85 eV or lower and with a Vox onset (SCE) of 0.49 V or higher.

22. The composition according to claim 21, wherein the 3-substituted thiophene repeat unit is a 3-alkyl substituted thiophene repeat unit.

23. The composition according to claim 21, wherein the 3-substituted thiophene repeat unit is a 3-substituent comprising a heteroatom.

24. The composition according to claim 21, wherein the 3-substituted thiophene repeat unit is a 3-substituent comprising an oxygen heteroatom.

25. The composition according to claim 21, wherein the 3-substituted thiophene repeat unit is a 3-substituent comprising an oxygen heteroatom directly bonded to the thiophene ring.

26. The composition according to claim 21, wherein the 3-substituted thiophene repeat unit is an alkoxy substituent.

27. The composition according to claim 21, wherein the 3-substituted thiophene repeat unit is a polyether substituent.

28. The composition according to claim 21, wherein the copolymer has a work function of −5.133 eV or lower and with a Vox onset of 0.773 V or higher.

29. A composition comprising a soluble, inherently conductive random copolymer comprising at least one 3-substituted thiophene repeat unit, wherein the 3-substituent comprises a heteroatom, and sufficient amount of unsubstituted thiophene repeat unit to provide the copolymer with a work function of −4.85 eV or lower and with a Vox onset (SCE) of 0.49 V or higher.

30. The composition according to claim 29, wherein the work function is at least −5.133 eV or lower.

31. The composition according to claim 29, wherein the Vox onset is 0.773 or higher.

32. The composition according to claim 29, wherein the work function is at least −5.133 eV or lower, and the Vox onset is 0.773 or higher.

33. The composition according to claim 29, wherein the heteroatom is oxygen.

34. The composition according to claim 29, wherein the 3-substituent comprises at least two heteroatoms.

35. The composition according to claim 29, wherein the 3-substituent comprises at least three heteroatoms.

36. The composition according to claim 29, wherein the 3-substituent comprises an alkoxy group.

37. The composition according to claim 29, wherein the 3-substituent comprises a polyether group.

38. A device comprising the compositions of claims 1, 21, or 29, wherein the device is a solar cell, a light emitting diode, a thin film semiconductor, a thin film conductor, a non-emitting diode, a transistor, an RFID tag, or a capacitor.

39. A photovoltaic cell comprising the composition according to claims 1, 21, or 29.

40. A block copolymer comprising a segment comprising a copolymer comprising at least one 3-substituted thiophene repeat unit and sufficient amount of unsubstituted thiophene repeat unit to provide the segment of copolymer with a work function of −4.85 eV or lower and with a Vox onset (SCE) of 0.49 V or higher.
